(19) United States
(12) Patent Application Publication
(10) Pub. No.: US 2011/0148309 A1
(43) Pub. Date: Jun. 23, 2011

(54) OCCUPANCY SENSOR WITH EMBEDDED SIGNALING CAPABILITY

(75) Inventors: Drew Reid, Brentwood, TN (US); William Stottlemyer, Mount Juliet, TN (US)

(73) Assignee: Schneider Electric USA, Inc., Palatine, IL (US)

(21) Appl. No.: 12/645,674

(22) Filed: Dec. 23, 2009

(51) Int. Cl. H05B 37/02; H01L 31/09; G01S 15/00

(52) U.S. Cl. 315/159; 250/338.1; 315/362; 315/360; 367/93; 315/76

(57) ABSTRACT

A lighting control system includes an enhanced occupancy sensor and/or an enhanced power pack, allowing for more sophisticated and/or accurate lighting control and energy management capability. In one example, the occupancy sensor provides additional information, such as information about movement detected in the monitored area, in the form of a signal superimposed on the occupancy signal, and a specialty power pack is configured to detect and respond to the superimposed information signal, thereby providing enhanced functionality to the lighting control system. The superimposed signal conveying the additional information is made high-speed/short-duration such that it is “invisible” to a conventional power pack and the occupancy sensor remains compatible with conventional power packs. The enhanced occupancy sensor may therefore be used seamlessly with both conventional and specialty power packs, and may be implemented as a “drop-in” component for legacy lighting control systems.

### BACKGROUND

1. Field of the Invention

The present invention relates generally to lighting control systems and, more particularly, to lighting control systems using networked occupancy sensors.

2. Discussion of Related Art

Many commercial or industrial facilities, as well as residential homes, require a significant number of lighting fixtures for adequate illumination, and therefore use a significant amount of power to operate the fixtures. Lighting is the largest single consumer of electric power in a typical building, often exceeding 30% of the total energy cost. In an effort to reduce costs in powering the light fixtures, as well as address environmental conservation concerns, intelligent lighting control systems employ sensors and controllers to automatically and selectively power the light fixtures on and off. The main function of an intelligent lighting control system is to provide light where and when it is needed and to reduce lighting in unoccupied areas. Such lighting control systems can provide significant energy and cost savings. In addition, lighting control helps to defer replacement costs of lamps and ballasts by reducing the number of annual burn hours.

Many lighting control systems employ occupancy sensors to conserve energy by activating and deactivating light fixtures automatically, depending upon occupancy of areas. Occupancy sensors typically provide a signal representing occupancy, which is derived from an occurrence of movement. Since an occupant is generally not continuously in motion, a time delay is added to an occurrence of movement to create a period of occupancy. This period of occupancy is assumed to represent an occupied area, such that the light fixtures in that area are activated and held on for as long as the area is occupied. The time delay that is used to create the period of occupancy is a preset time interval that is typically between three and sixty minutes in duration.

Referring to FIG. 1, occupancy sensor devices in a conventional lighting control system are often split into two components, namely, a power pack 110 and an occupancy sensor 120. The sensor 120 receives operating power (on line 140) from the power pack 110 and provides a signal (on line 150) to the power pack 110, the signal representing occupancy of a monitored area. The occupancy signal on line 150 is used by the power pack 110 to control an internal relay 130. The relay 130 closes in response to the occupancy signal to activate a lighting fixture 160 connected through the relay 130.

There are several different types of occupancy sensors used by current lighting control systems, including, for example, passive infrared (“PIR”) sensors and ultrasonic sensors. PIR sensors activate lighting fixtures whenever a moving or additional heat source is detected. Ultrasonic sensors emit ultrasonic vibrations at frequencies of 25 kHz or higher and listen to the return of echoes. If a significant Doppler shift is detected, the ultrasonic sensor indicates a high probability that there is movement in the area. Ultrasonic sensor technology allows continuous detection of moving objects that reflect ultrasonic acoustic energy. The lighting fixtures are then activated in response to the detected movement.

### SUMMARY OF INVENTION

The conventional occupancy sensor and power pack combination discussed above with reference to FIG. 1 provides a simple, basic level of energy management of lighting loads; however, the energy management capability is limited, in particularly, due to the singular purpose of the occupancy signal line 150 and limited functionality of the power pack 110. Therefore, a need exists for a power pack and occupancy sensor combination that can provide a higher level of energy management, while preferably also being easy to use, simple to install, and cost effective.

Accordingly, aspects and embodiments of the present invention are directed to a lighting control system which includes an enhanced occupancy sensor and/or an enhanced power pack, allowing for more sophisticated and/or accurate lighting control and energy management capability. An enhanced occupancy sensor provides additional information, such as information regarding movement detected in the monitored area, in the form of a short-duration/high frequency signal superimposed on the occupancy signal. The superimposed signal conveying the additional information is made high-speed/short-duration such that it is “invisible” to a conventional power pack, and thus the occupancy sensor remains compatible with conventional power packs. However, a specialty power pack according to embodiments of the present invention is configured to detect and respond to the superimposed information signal, thereby providing enhanced functionality to the lighting control system, as discussed further below. In addition, the programming to provide the superimposed information signal can be implemented in the firmware and/or software of the occupancy sensor, thus requiring little or no change to the hardware of the occupancy sensor. The enhanced occupancy sensor may therefore be used seamlessly with both conventional and specialty power packs, and may be implemented as a “drop-in” component for legacy lighting control systems.

Furthermore, the power pack and/or occupancy sensor can be made networkable, providing the capability to link and coordinate multiple power pack/occupancy sensor combinations, thereby providing zone-wide control and energy management features, such as, for example, coordinated lighting of several areas, the ability to force lights on in a life-safety situation, and the ability to control other equipment in a monitored area (e.g., an air conditioning and/or heating system) responsive to detected occupancy in the area. In one example, a networkable power pack includes installation and wiring to an occupancy sensor that is substantially identical to a conventional power pack and the power pack therefore also may be implemented as a “drop-in” component in a legacy lighting control system, without requiring changes to the occupancy sensors or wiring of the system.

According to one embodiment, a lighting control system comprises an occupancy sensor configured to provide an occupancy signal representative of occupancy of an area and a movement signal superimposed on the occupancy signal, the movement signal representative of movement activity in the area, and a power pack coupled to the occupancy sensor and configured to receive the occupancy signal and the movement signal, the power pack comprising a relay configured to be coupled to a lighting circuit, and the power pack being configured to actuate the relay responsive to at least one of the occupancy signal and the movement signal.

In one example, the occupancy sensor is a passive infrared sensor. In another example, the occupancy sensor is an ultrasonic sensor. In one example, the occupancy signal is a DC voltage signal having a predetermined voltage level. In another example, the movement signal comprises a plurality of drops to zero volts from the predetermined voltage level, each drop followed by a rise to the predetermined voltage level. The predetermined voltage level may be, for example, approximately +24Vdc. In one example, the power pack is configured to supply power to the occupancy sensor. In one example, the lighting control system further comprises a network, and a controller coupled to the network and configured to provide a control signal, wherein the power pack comprises a communications interface coupled to the network and configured to receive the control signal and to provide information to the controller. The information may include, for example, information derived from at least one of the occupancy signal and the movement signal. In one example, the network is a C-Bus™ network. “C-Bus” is a trademark of Schneider Electric. In another example, the controller is configured to override the occupancy signal and control the power pack to actuate the relay responsive to the control signal. In another example, the lighting control system further comprises a timer coupled to the power pack and configured to receive information derived from the movement signal and to generate a time delay based on the information to set a period of occupancy for the monitored area.

According to another embodiment, a method of controlling a lighting circuit comprises acts of receiving an occupancy signal representative of an occupancy status of an area, detecting a second signal superimposed on the occupancy signal, and controlling the lighting circuit responsive to at least one of the occupancy signal and the second signal.

In one example of the method, detecting the second signal includes detecting a movement signal representative of movement activity within the area. Detecting the movement signal may include, for example, detecting on a signal line a voltage rise from approximately zero volts to a predetermined voltage level. The method may further comprise an act of communicating information derived from at least one of the occupancy signal and the movement signal to a remote device via a network. In one example, the method further comprises acts of receiving a control signal from the remote device via the network, and controlling the lighting circuit responsive to the control signal. Controlling the lighting circuit may include, for example, actuating a relay to turn on the lighting circuit responsive to the occupancy signal indicating that the occupancy status of the area is occupied. The method may further comprise communicating information derived from the movement signal to a timer, setting a period of occupancy for the area based on the information provided to the timer, and holding the lighting circuit on for a duration of the period of the occupancy.

According to another embodiment, an occupancy sensor comprises a sensor configured to detect movement in a monitored area, and a signal output coupled to sensor, wherein the occupancy sensor is configured to produce at the signal output an occupancy signal indicating that the monitored area is occupied responsive to a first instance of detected movement in the monitored area, and a movement signal superimposed on the occupancy signal. In one example, the occupancy signal is a DC voltage signal having a predetermined voltage level, such as, for example, +24Vdc. In another example, the movement signal comprises a plurality of drops to approximately zero volts from the predetermined voltage level, each drop followed by a rise to the predetermined voltage level. In one example, the occupancy sensor is configured to cause each drop of the plurality of drops to approximately zero volts responsive to an additional instance of movement detected by the sensor. The sensor may be, for example, an ultrasonic sensor or an infrared sensor.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Any embodiment disclosed herein may be combined with any other embodiment in any manner consistent with at least one of the objectives, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description, or any claim are followed by references signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1 is a block diagram of a conventional occupancy sensor and power pack combination;

FIG. 2 is a block diagram of one example of an occupancy sensor and power pack combination according to aspects of the invention;

FIG. 3 is a signal diagram illustrating one example of a movement signal superimposed on an occupancy signal, in accordance with aspects of the invention;

FIG. 4 is a block diagram of another example of an occupancy sensor and power pack combination according to aspects of the invention;

FIG. 5 is a block diagram of one example of a C-Bus™ network configuration; and

FIG. 6 is a block diagram of one example of a network-connected occupancy sensor according to aspects of the invention.

### DETAILED DESCRIPTION

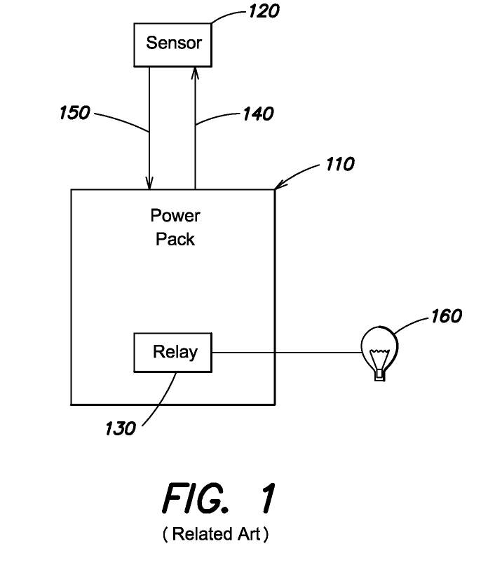

The occupancy sensor and power pack combination discussed above with reference to FIG. 1 provides a simple and effective solution to energy savings; however, the solution is limited due to the singular purpose of the signal line 140 and limited functionality of the power pack 110. As discussed above, a conventional power pack 110 provides two functions, namely supplying power to the occupancy sensor 120 and switching an electrical load (e.g., lighting fixture 160) based on an occupancy signal from the occupancy sensor 120. Although this conventional approach provides the most basic functionality for energy management of lighting loads, other desired capabilities are not supported. In addition, many applications would benefit from receiving additional information from the occupancy sensor 120 beyond merely a simple occupancy signal, for example, by allowing for more sophisticated and/or accurate lighting and other systems control.

Accordingly, aspects and embodiments are directed to lighting control systems and methods that employ improved power packs and/or occupancy sensors capable of processing and/or providing additional information and thereby provide enhanced lighting control capabilities. In addition, according to some embodiments, improved power packs are capable of being networked together, for example, via a network bus, wireless communication link, or other networking system, as discussed further below. The occupancy sensor and power pack together can be considered an “island of control” that controls one or more lighting fixtures connected to the power pack. As a stand-alone control system, the ability to coordinate one or more islands of control is not possible. In contrast, aspects and embodiments are directed to lighting control systems and methods that include linking two or more islands of control together to form a “zone of control,” thereby enabling enhanced control options such as, for example, overriding the occupancy status for a given island of control as part of a zone-wide control strategy, as discussed further below.

It is to be appreciated that embodiments of the methods and apparatus discussed herein are not limited in application to the details of construction and the arrangement of components set forth in the following description or illustrated in the accompanying figures. The methods and apparatus are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

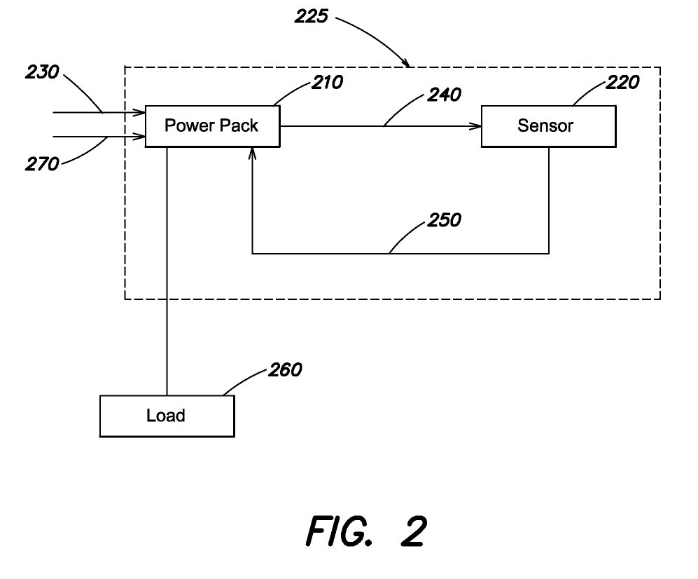

Referring to FIG. 2, there is illustrated a block diagram of one example of a power pack 210 and occupancy sensor 220 which together form an island of control 225. As discussed above, the power pack 210 provides power to the occupancy sensor 220 via line 240. The occupancy sensor may be a passive infrared sensor, an ultrasonic sensor, or a dual infrared-ultrasonic sensor, for example. The power provided by the power pack 210 may typically be DC (direct current) power, which may be provided via any suitable wiring connection, including, for example, a low voltage/low current three-wire or two-wire circuit, or an RJ-type connector and wiring. Thus, although line 240 is illustrated as a single line, it is to be appreciated that line 240 may represent multiple physical wiring lines. The power pack 210 may itself receive power from an external source via power line 230. Again, it is to be appreciated that the power line 230 may represent multiple physical lines depending, for example, on the type of wiring used. Alternatively, the power pack may be powered by an internal battery (not shown).

The occupancy sensor 220 provides an occupancy signal to the power pack 210 on signal line 250. Conventionally, the occupancy signal is either a constant level voltage, for example, 24 Volts (+24Vdc), or no voltage (0V). According to one embodiment, the occupancy sensor 220 is configured with an embedded signaling method to provide additional information on the signal line 250, as discussed further below. It is to be appreciated that although signal line 250 is illustrated as a single line in FIG. 2, it may represent multiple physical lines or links in some embodiments. The power pack 210 controls a load 260, which may include one or more lighting circuits, via one or more internal relays (not shown) responsive to the signal received from the occupancy sensor 220. The power pack 210 may also receive a signal on line 270 from an external control panel, computer, or other device, as also discussed further below.

According to one embodiment, the occupancy sensor 220 is configured to provide additional information, for example, a signal representative of movement rather than occupancy, in addition to the occupancy signal. As discussed above, many applications would benefit from receiving information in addition to the occupancy signal from the occupancy sensor 220. For example, if the occupancy sensor supplies a movement signal, an external timer can be configured to receive the movement signal (or a signal representative of the movement signal) and the movement information can be used to generate the time delay to create the period of occupancy discussed above. An external timer system may not be reliable based on the conventional occupancy signal because repeated motion by the occupant could continually trigger the sensor, causing the signal to stay in the occupied state and therefore not supply updated information to the external timer. The occupancy sensor 220 may be modified to supply a movement signal on an additional signal line; however, this solution may require another signal line, a different sensor product, and/or an option to select an additional mode of operation of the sensor. As a result, application difficulties may arise due to miswiring, installation of the wrong sensor product, or selection of the wrong mode of operation.

An innovative solution to this problem is provided by one embodiment in which the occupancy sensor 220 is configured to superimpose a short-duration movement signal onto the occupancy signal. In this embodiment, the occupancy sensor operates normally with a conventional power pack, but will also report movement to a power pack 210 (or other device) that is configured to receive the movement signal. In one example, the movement signal is superimposed on the same signal line 250 that may be alternately used with a conventional power pack to report occupancy, as discussed above. The movement signal is made high-speed/short-duration such that it does not disrupt reporting of the occupancy signal to a conventional power pack, and the conventional power pack does not respond to the high-speed movement signal. However, a specialty power pack according to embodiments of the present invention is configured to detect and extract the movement signal, as discussed further below. Thus, according to at least one embodiment, the occupancy sensor 220 provides a real-time movement signal to a device, such as a specialty power pack 210, connected to the occupancy sensor in a manner such that the occupancy sensor remains compatible with conventional power packs and may be used seamlessly with both conventional and specialty power packs.

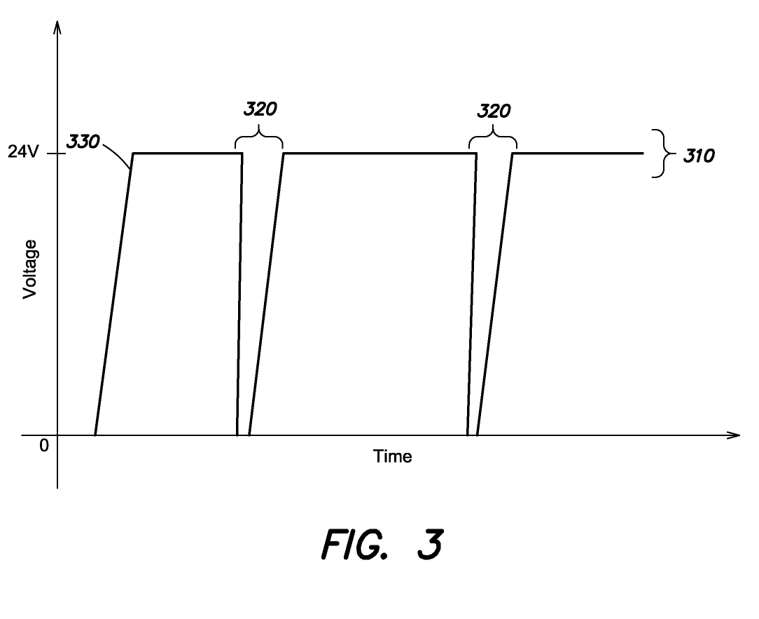

According to one embodiment, occupancy is indicated by a voltage level on the signal line 250. In one example, the voltage level to indicate occupancy is +24Vdc; however, it is to be appreciated that other voltage levels may be used consistent with appropriate signal levels for various applications. In one example, first movement in a monitored space is indicated when the signal line voltage rises from 0V to +24Vdc. Each additional movement as detected by the occupancy sensor is indicated by a momentary drop to 0V followed by a rise again to +24Vdc. An example of this signaling is illustrated in FIG. 3. The predominantly constant +24Vdc signal 310 constitutes the occupancy signal, and the momentary drops 320 to 0V, followed by rises returning the signal to +24Vdc, constitute the superimposed movement signal, with each drop 320 followed by a rise indicating an instance of movement. The first rise 330 is the first instance of movement and also triggers the occupancy signal. Those skilled in the art will recognize, given the benefit of this disclosure, numerous variations on this signaling method, which are intended as part of this disclosure. For example, the occupancy signal level need not be +24Vdc, but may instead be any suitable voltage level. Similarly, an inverse signaling method may be used, where occupancy is indicated by a 0V level and instances of movement are indicated by momentary signal rises to a predetermined voltage level, followed by returns to 0V.

Still referring to FIG. 3, in one embodiment, the duration of the drop 320 is selected to be short with respect to response time of a conventional power pack relay that may be driven from the signal line 250. As a result, the superimposed movement signal is not detected by a conventional power pack and accordingly, the occupancy sensor 220 can be used with a conventional power pack without modification. Thus, in one embodiment and application, the movement signal is a hidden feature within an otherwise standard occupancy sensor. A specialty power pack 210 with electronic circuitry configured to detect each rise from 0V to +24Vdc (or other movement signaling method), however, receives real-time movement information. Thus, the occupancy sensor 220 may be used seamlessly with conventional power packs or with specialty power packs 210 which are able to make use of the additional information provided by the occupancy sensor. Real-time monitoring of movement in areas can help building owners or managers understand facility utilization by monitoring movement patterns, and provide information that can be used to improve energy management in a building or area. In one embodiment, the programming to provide the movement signal is added to the firmware and/or software of the occupancy sensor 220 (in addition to the normal operating code), thus requiring little or no change to the hardware of the occupancy sensor. As a result, the enhanced occupancy sensor may be implemented as a “drop-in” component to legacy lighting control systems, with few or no hardware changes required to either the sensor itself or the lighting control system.

In the above-discussed embodiments, the occupancy sensor 220 is configured to provide a movement signal, in addition to the occupancy signal, to the power pack 210. In another embodiment, the occupancy sensor 220 is configured to provide a signal, in addition to the occupancy signal, representative of information other than movement. This additional information signal may be provided in the same way as discussed above for providing the movement signal. The additional information may include, for example, ambient light conditions at the occupancy sensor 220, diagnostic and/or maintenance information, for example, pre-set sensitivity levels of the occupancy sensor, whether the occupancy sensor is using ultrasonic or infrared detection, and whether the motion detected was major or minor movement (according to pre-set definitions).

As discussed above, in one embodiment, individual islands of control 225, are networked together to form a zone of control, thereby enabling enhanced control and energy management features. It is also to be appreciated that individual power packs 210, with or without associated occupancy sensors 220, may be networked together to form a zone of control. In a system that includes only stand-alone islands of control, the ability to co-ordinate two or more islands of control is lacking. In contrast, a networkable power pack 210 according to aspects and embodiments provides the capability to connect the power packs to an external control system, allowing the information from an associated occupancy sensor to be reported to the control system for monitoring or as input to a larger-scale control scheme. For example, information gathered from monitoring occupancy in an area may be used to signal an air conditioning and/or heating system to maintain comfort in the occupied area. In addition, in one embodiment, the lighting fixture(s), or other load 260, associated with an island of control can be controlled (i.e., turned on or off), via the power pack 210, by an external command, provided for example, on line 270. Allowing external control (i.e., from outside the island of control formed by a power pack and its associated occupancy sensor) of the switching of a load 260 may provide several benefits and advantages, such as, for example, coordinated lighting of several areas, such as along an egress path from a building, and the ability to force lights on in a life-safety situation, such as the occurrence of a fire or security alarm. Similarly, allowing external control of the switching of the load 260 may provide the ability to override the occupancy signal from one or more occupancy sensors and turn off lights or other loads in a given area, regardless of the occupancy status of the area, as part of overall control/energy management strategy. This capability is becoming more desirable as the cost of energy increases.

According to one embodiment, a specialty networkable power pack 210 according to aspects and embodiments may provide desired control and coordination functionality, as in the examples discussed above, in a simple and efficient manner, without requiring complex and costly building automation and/or networked lighting control systems. In one embodiment, a specialty power pack 210 includes installation and wiring to an occupancy sensor 220 that is identical to a conventional power pack 110, and further includes a system connection to support zone-wide (e.g., building-wide, floor-wide, etc.) control strategies. It is to be appreciated that the networkable power packs 210 may be used with conventional occupancy sensors 120 and/or enhanced occupancy sensors 220 discussed above. Thus, the networkable power packs may be implemented as “drop-in” components in a legacy lighting control system, without requiring changes to the occupancy sensors or wiring of the system. The networkable power pack may thus provide enhanced functionality in a lighting control system, with minimal changes to the overall system, thus providing an easy to implement and cost effective “upgrade” to legacy lighting control systems.

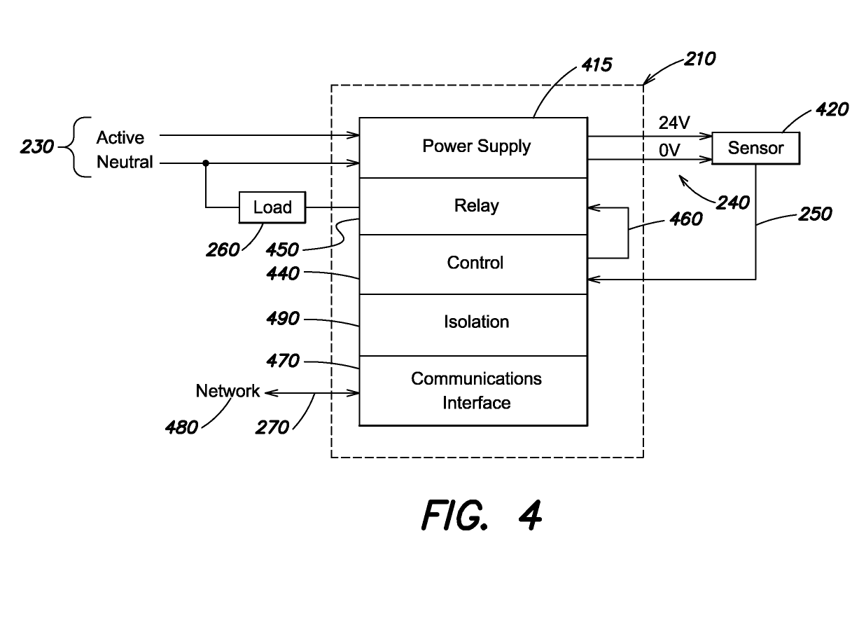

Referring to FIG. 4, there is illustrated a functional block diagram of one example of a specialty power pack 210 coupled to an occupancy sensor 420 and a load 260, according to one embodiment. As discussed above, the power pack 210 provides supply voltage, for example, +24Vdc, to the connected occupancy sensor 420 over line(s) 240. Thus, the power pack 210 includes a power supply 415 that receives power on lines 230 and provides power to the occupancy sensor 420 on line(s) 240. As discussed further below, the occupancy sensor 420 may be a conventional occupancy sensor 120 or an enhanced occupancy sensor 220. In one example, the power supply 415 is preferably a switch mode power supply to handle a wide input voltage range.

As discussed above, the occupancy sensor 420 reports an occupancy signal, and optionally a superimposed movement signal or other information, to the power pack 210 on signal line 250. The power pack 210 monitors the information provided on the signal line 250 and uses power control circuitry 440 to determine the desired control state of a connected relay 450, which is internal to the power pack 210 as illustrated in FIG. 4. In other embodiments, relay 450 may be external to the power pack 210. It is also to be appreciated that the relay 450 may be replaced with another load switching device, such as, for example, silicon controlled rectifiers (SCRs), Triacs, transistors, or other electrical load switching devices that may be controlled by power control circuitry 440. The power control circuitry 440 may include, for example, a programmable controller, microprocessor, or other control circuitry capable of accepting and interpreting one or more externally originating signals provided from the occupancy sensor 220 and/or line 270 discussed above. The control circuitry 440 is also capable of providing control signals to actuate the relay 450. The control circuitry 440 is also capable of interpreting the occupancy signal, optionally the superimposed movement signal discussed above, and the externally originating control signal from line 270 into control signals to actuate the relay 450. As discussed above, the relay 450 is used to control power to a connected load 260. Line 460 represents the flow of the control signals from the control circuitry 440 to the relay 450.

In one embodiment, the power pack 210 further includes a communications interface 470 that allows the power pack 210 to be connected to and communicate with a network 480. The communications interface 470 allows the power pack 210 to receive control signals (for example, an override signal as discussed above) and/or information, such as the status of another network-connected device, from an external controller via the network 480. Likewise, the power pack 210 may provide information, for example, the signal(s) sent from the occupancy sensor 420 and/or a status of the sensor, to external components coupled to the network 480 via the communications interface 470. In one example, the network 480 is a C-Bus™ network used by various control systems available from the Schneider Electric company. The communications interface 470 may include a connector, such as an EIA/TIA Category 5 connector or RJ-45 connector for connection to network wiring, or a wireless transceiver for wireless connection to network 480. The power pack 210 may also include isolation circuitry 490 to isolate the occupancy sensor 420 from the communications interface 470 and network 480, as discussed further below.

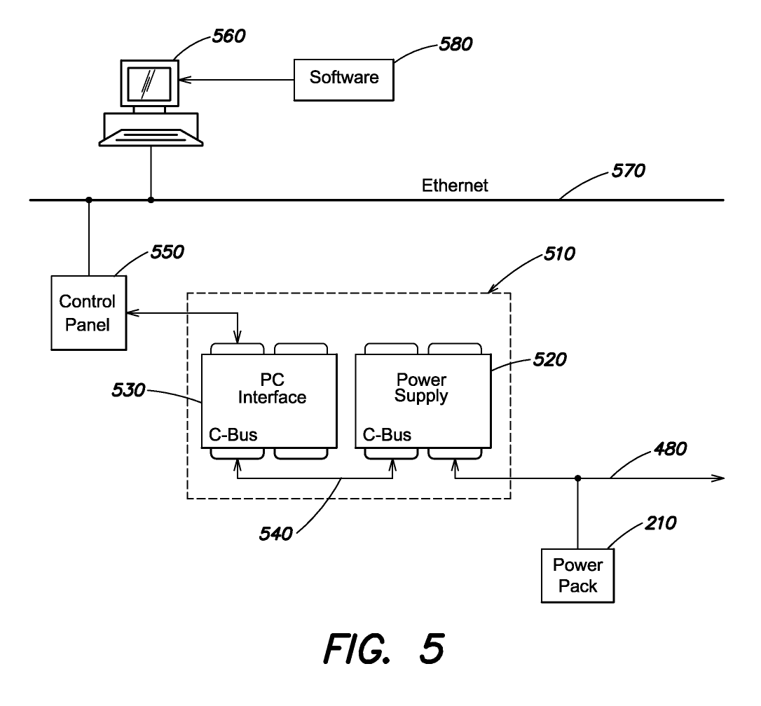

Referring to FIG. 5, there is illustrated one example of a control system including a power pack 210 coupled to the system via a C-Bus™ network 480. The C-Bus™ network includes a router 510 that includes a power supply 520 coupled to an interface device 530, as indicated by connection 540. The router 510 is coupled to a control panel 550 that in turn is coupled to a computer system 560 via a communications link, such as an Ethernet link 570. Control software 580 may be downloaded onto the computer 560 to allow the computer to interface with, and optionally control, the control panel 550 and/or devices, such as the power pack 210, connected to the C-Bus™ network. It is to be appreciated that FIG. 5 illustrates one example of a C-Bus™ network and control system; however, there may be numerous variations of a C-Bus™ network, and the power pack 210 may be coupled to other power packs and/or other devices using many different networks 480, not limited to a C-Bus™ network or to the specific example illustrated in FIG. 5.

According to one embodiment, the power pack 210 is configured to operate with a conventional occupancy sensor 120 with no interposing interfaces or additional power pack to sensor wiring required. The power pack 210 receives the occupancy signal from the occupancy sensor 420 and may then use the occupancy signal, as in conventional systems, to drive the relay 450, and/or may communicate the occupancy signal or other information to an external device via the communications interface 470 and network 480. In one example, the control circuitry 440 receives the occupancy signal from the occupancy sensor 420 and determines whether to allow the relay 450 to actuate responsive to the occupancy signal or whether to override the occupancy signal and control the relay based on a signal received via the communications interface 470. Thus, zone-wide control may be achieved using conventional occupancy sensors that are controlled and coordinated via networked power packs 210.

As discussed above, according to one embodiment, the occupancy sensor 420 is configured to provide additional information, such as a movement signal, for example, superimposed on the occupancy signal on line 250. Accordingly, the control circuitry 440 may be configured to monitor and respond to this superimposed signal. Thus, the occupancy sensor 420 reports occupancy status of its associated monitored area as well as movement activity in the area to the control circuitry 440 of the power pack 210. In one example, occupancy is indicated by +24Vdc on the signal line 250, no occupancy by 0 Vdc on the signal line, and movement activity is reported as a 1 millisecond (ms) pulse (+24Vdc to 0Vdc) each time movement is detected by the occupancy sensor 420. As discussed above, with reference to FIG. 3, a rising edge in the signal indicates that movement has been detected. The control circuitry 440 may take any of numerous actions in response to detection of the movement signal. For example, the control logic 440 may be configured to determine whether to allow the relay 450 to be responsive to the occupancy signal, the movement signal, or to another signal received via the communications interface 470, which may override the occupancy and/or movement signal. As discussed above, the movement signal may be used to control a timer, which may be internal to the power pack 210 or externally connected to either the power pack 210 or the occupancy sensor 420. In addition, supplying the movement signal (or information representative of the movement signal) to an external device via the communications interface 470 and network 480 may allow for remote adjustment/control of the timer or of another device.

Still referring to FIG. 4, in one embodiment, various aspects and/or functions of the power pack 210 are controlled by an external device via the network 480 and the communications interface 470. For example, as discussed above, in some instances, a control signal supplied via the communications interface 470 may be used to override the occupancy and/or movement signal provided by the occupancy sensor 420. Thus, where the network 480 is a C-Bus™ network, the relay 450 may be switched by a C-Bus™ device connected to the network 480, rather than by the power pack 210. In another embodiment, the power pack 210 is powered via the C-Bus™ network 480, thus obviating the need for the power lines 430. The occupancy sensor 420 may also be powered via the C-Bus™ network 480, rather than by the power supply 415. When the occupancy sensor 420 is powered via the C-Bus™ network 480, the sensor may be referred to as being in a non-isolated mode. As discussed above, the power pack 210 may include isolation circuitry 490 that isolates the occupancy sensor 420 from the C-Bus™ network 480, and the occupancy sensor is therefore powered by the power supply 415.

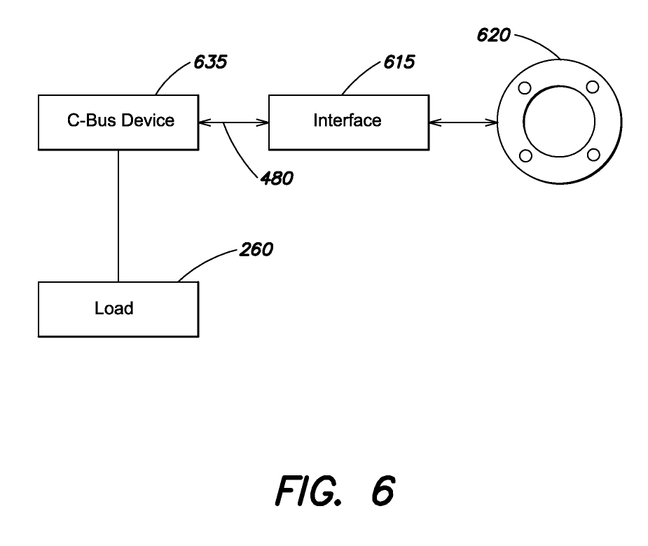

According to another embodiment, an occupancy sensor 620 may be coupled directly to a C-Bus™ network, without an intervening power pack 210. A block diagram of an example of such a system is illustrated in FIG. 6. A network interface 615 is used to achieve communication between the C-Bus™ network 480 and the occupancy sensor 620. The network interface 615 may be external to the occupancy sensor 620 and connected to the occupancy sensor, as illustrated in FIG. 6, or may be integrated with the occupancy sensor. A C-Bus™ device or controller 635 may be coupled to the C-Bus™ network 480 and may monitor the signals (e.g., occupancy and/or movement) supplied by the occupancy sensor 620. The C-Bus™ device or controller 635 may switch a load 260 responsive to a signal from the occupancy sensor 620. Thus, in this configuration, the power pack 110/210 may be eliminated and the occupancy sensor 620 may interface directly with the C-Bus™ network, or with a controller connected via another type of network. In another example, the network interface 615 may include a power supply to power the occupancy sensor 620. Thus, the occupancy sensor 620 may operate in an isolated mode, receiving power from the network interface 615, or a non-isolated mode, receiving power from the C-Bus™ network 480. In one example, the network interface 615 may be considered a type of power pack, and the interface-occupancy sensor combination may therefore be similar or analogous to an integrated power pack-occupancy sensor combination.

Referring again to FIG. 4, in another embodiment, the power pack 210 may include, or may be connected to, a second relay 450 (not shown in FIG. 4) to allow bi-level lighting control. In another example, the power pack 210 may provide a variable current output through the relay 450, for example, 4-20 mA, thereby allowing dimming control of a load 260 with appropriate ballast. According to another embodiment, the power pack 210 may be used as a control point within the C-Bus™ (or other) network 480 without a connected occupancy sensor 420. For example, the power pack 210 as a control point without a sensor may include a keypad or other manual input to allow an operator to influence aspects of a networked lighting control system.

Thus, according to various aspects and embodiments, a lighting control system may include an enhanced occupancy sensor 220 which may provide additional information, such as a movement signal, superimposed on its conventional occupancy signal, a specialty power pack configured to detect and monitor the superimposed information signal, a networkable power pack or occupancy sensor, or any combination of these. As discussed above, embodiments include the used of an enhanced occupancy sensor with a conventional power pack, an enhanced power pack with a conventional occupancy sensor, as well as the combination of an enhanced occupancy sensor with a networkable power pack capable of detecting and responding to the additional information provided by the enhanced occupancy sensor. Additionally, embodiments include networkable occupancy sensors which may be used with a C-Bus™ network, for example, with or without an associated power pack, as well as a networkable power pack which may be used with or without a connected occupancy sensor. As discussed above, each of these embodiments may provide benefits and advantages for building control and/or energy management over the conventional island of control that includes only a conventional power pack with an associated conventional occupancy sensor.

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the invention. For example, any of the connections and/or communications links illustrated and discussed above may be wired or wireless links. Similarly, although the disclosure refers primarily to occupancy sensors, other types of sensors may be used in addition to or instead of occupancy sensors, such as, for example, light level sensors, motion sensors, fire and/or smoke detectors, water sensors, etc. Accordingly, the foregoing description and drawings are by way of example only, and the scope of the invention should be determined from proper construction of the appended claims, and their equivalents.

What is claimed is:

1. A lighting control system comprising:
an occupancy sensor configured to provide an occupancy signal representative of occupancy of an area and a movement signal superimposed on the occupancy signal, the movement signal representative of movement activity in the area; and
a power pack coupled to the occupancy sensor and configured to receive the occupancy signal and the movement signal, the power pack comprising a relay configured to be coupled to a lighting circuit, and the power pack being configured to actuate the relay responsive to at least one of the occupancy signal and the movement signal.

2. The lighting control system as claimed in claim 1, wherein the occupancy sensor is a passive infrared sensor.

3. The lighting control system as claimed in claim 1, wherein the occupancy sensor is an ultrasonic sensor.

4. The lighting control system as claimed in claim 1, wherein the occupancy signal is a DC voltage signal having a predetermined voltage level.

5. The lighting control system as claimed in claim 4, wherein the movement signal comprises a plurality of drops to approximately zero volts from the predetermined voltage level, each drop followed by a rise to the predetermined voltage level.

6. The lighting control system as claimed in claim 5, wherein the predetermined voltage level is approximately +24Vdc.

7. The lighting control system as claimed in claim 1, wherein the power pack is configured to supply power to the occupancy sensor.

8. The lighting control system as claimed in claim 1, further comprising:
a timer coupled to the power pack and configured to receive information derived from the movement signal and to generate a time delay based on the information to set a period of occupancy for the area.

9. A method of controlling a lighting circuit, the method comprising:
receiving an occupancy signal representative of an occupancy status of an area;
detecting a second signal superimposed on the occupancy signal; and
controlling the lighting circuit responsive to at least one of the occupancy signal and the second signal.

10. The method as claimed in claim 9, wherein detecting the second signal includes detecting a movement signal representative of movement activity within the area.

11. The method as claimed in claim 10, wherein detecting the movement signal includes detecting on a signal line a voltage rise from approximately zero volts to a predetermined voltage level.

12. The method as claimed in claim 10, wherein controlling the lighting circuit includes actuating a relay to turn on the lighting circuit responsive to the occupancy signal indicating that the occupancy status of the area is occupied.

13. The method as claimed in claim 12, further comprising communicating information derived from the movement signal to a timer.

14. The method as claimed in claim 13, further comprising:
at the timer, setting a period of occupancy for the area based on the information; and
holding the lighting circuit on for a duration of the period of the occupancy.

15. An occupancy sensor comprising:
a sensor configured to detect movement in a monitored area; and
a signal output coupled to sensor;
wherein the occupancy sensor is configured to produce at the signal output an occupancy signal indicating that the monitored area is occupied responsive to a first instance of detected movement in the monitored area, and a movement signal superimposed on the occupancy signal.

16. The occupancy sensor as claimed in claim 15, wherein the occupancy signal is a DC voltage signal having a predetermined voltage level.

17. The occupancy sensor as claimed in claim 16, wherein the predetermined voltage level is approximately +24Vdc.

18. The occupancy sensor as claimed in claim 16, wherein the movement signal comprises a plurality of drops to approximately zero volts from the predetermined voltage level, each drop followed by a rise to the predetermined voltage level.

19. The occupancy sensor as claimed in claim 18, wherein the occupancy sensor is configured to cause each drop of the plurality of drops to approximately zero volts in response to an additional instance of movement detected by the sensor.

20. The occupancy sensor as claimed in claim 15, wherein the sensor is an ultrasonic sensor.

21. The occupancy sensor as claimed in claim 15, wherein the sensor is an infrared sensor.
